(19) United States
(12) Patent Application Publication
(10) Pub. No.: US 2008/0035929 A1
(43) Pub. Date: Feb. 14, 2008

(54) ORGANIC LIGHT EMITTING DISPLAY DEVICES AND METHODS FOR FABRICATING THE SAME

(75) Inventors: Yun-Sheng Chen, Tainan City (TW); Ming-Chang Shih, Changhua County (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: AU OPTRONICS CORP., Hsinchu (TW)

(21) Appl. No.: 11/559,430

(22) Filed: Nov. 14, 2006

(30) Foreign Application Priority Data
Aug. 10, 2006 (TW) 95129388

(51) Int. Cl. H01L 29/04; H01L 29/08; H01L 33/00

(52) U.S. Cl. 257/72; 257/40; 257/103

(57) ABSTRACT

Organic light emitting display (OLED) devices and methods for fabricating the same are disclosed. An exemplary OLED device comprises a substrate with a thin film transistor (TFT) formed over a first portion thereof. A color filter layer is formed over a second portion of the substrate. A planarization layer overlies the color filter layer and the TFT. A pair of openings is formed through the planarization layer and portions of the TFT, respectively exposing a source/drain region of the TFT. A pair of conductive layers conformably covers the openings and portions of the planarization layer adjacent thereto, electrically connecting one of the source/drain regions of the TFT, wherein one of the conductive layers extends toward the color filter layer and the conductive layers are electrically isolated from each other. An anode is formed over the planarization, partially covering the conductive extending toward the color filter layer.

### BACKGROUND OF THE INVENTION

1. Field of the Invention

The invention relates to flat panel displays, and more particularly to organic light emitting display (OLED) devices and methods for fabricating the same.

2. Description of the Related Art

Among flat panel techniques, organic electroluminescent displays, such as organic light emitting diode (OLED) displays, are endowed with self-luminescence, wide-viewing angle, thin profile, low weight, low driving voltage and simple fabrication process. In laminated OLED displays, organic compounds such as dyes, polymers, or other luminescent materials serve as the organic luminescent layer and are disposed between an anode and a cathode. OLED displays are classified into passive matrix and active matrix types depending on the driving mode.

Electrical current drives active matrix OLED (AM-OLED) displays. Each of matrix-array pixel regions has at least one thin film transistor (TFT) serving as a switch modulating the driving current based on the variation in capacitor storage potential for controlling the brightness and gray level of the pixel regions. Active matrix OLED (AM-OLED) displays possess increased scan lines, thus, large size, high resolution are achieved. AM-OLED displays are typically driven by two TFTs in each pixel region, or four TFTs in each pixel region.

AM-OLED displays comprise a plurality of pixel units emitting colors such as green, red and blue for presenting color images. Materials used in the pixel units for emitting different color lights, however, have different life spans, thus, imaging performance and the life span of the AM-OLED suffers.

Patent application JP 2000-077191 discloses an AM-OLED having pixel units emitting only white light. The AM-OLED presents a color image through incorporation of an additional color filter film. Thus, life span differences between pixel units can be reduced. Additional elements and fabrication steps are however required and production costs inevitably increase.

### BRIEF SUMMARY OF THE INVENTION

An improved OLED device with reduced production costs and fabrication steps is desirable.

Organic light emitting display devices are provided. An exemplary embodiment of an organic light emitting display device comprises a substrate with a thin film transistor (TFT) formed over a first portion thereof. A color filter layer is formed over a second portion different from the first portion of the substrate. A planarization layer overlies the color filter layer and the TFT. A pair of openings is formed through the planarization layer and portions of the TFT, respectively exposing a source/drain region of the TFT. A pair of conductive layers conformably covers the openings and portions of the adjacent planarization layer, electrically connecting one of the source/drain regions of the TFT, wherein one of the conductive layers extends toward the color filter layer and the conductive layers are electrically isolated from each other. An anode is formed over the planarization layer, partially covering the conductive extending toward the color filter layer.

Methods for fabricating organic light emitting display devices are provided. An exemplary embodiment of a method for fabricating an organic light emitting display device comprises providing a substrate. A thin film transistor (TFT) is formed over a first portion of the substrate, wherein a gate dielectric of the TFT covers at least the first portion of the substrate. A color filter layer is formed over a second portion different from the first portion of the substrate. A planarization layer covers the color filter layer and the TFT. A pair of openings is formed, through the planarization layer and portions of the TFT, respectively exposing a source/drain region of the TFT. A pair of conductive layers is conformably formed, respectively covering the openings and portions of the planarization layer adjacent thereto, wherein one of the conductive layers extends toward the color filter layer and the conductive layers are electrically isolated from each other. An anode is formed over the planarization layer, wherein the anode partially covers the conductive layer extending toward the color filter layer.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIGS. 1-4 are a series of cross sections showing a method for fabricating an organic light emitting display device according to an embodiment of the invention; and

FIG. 5 is a cross section showing an OLED device according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

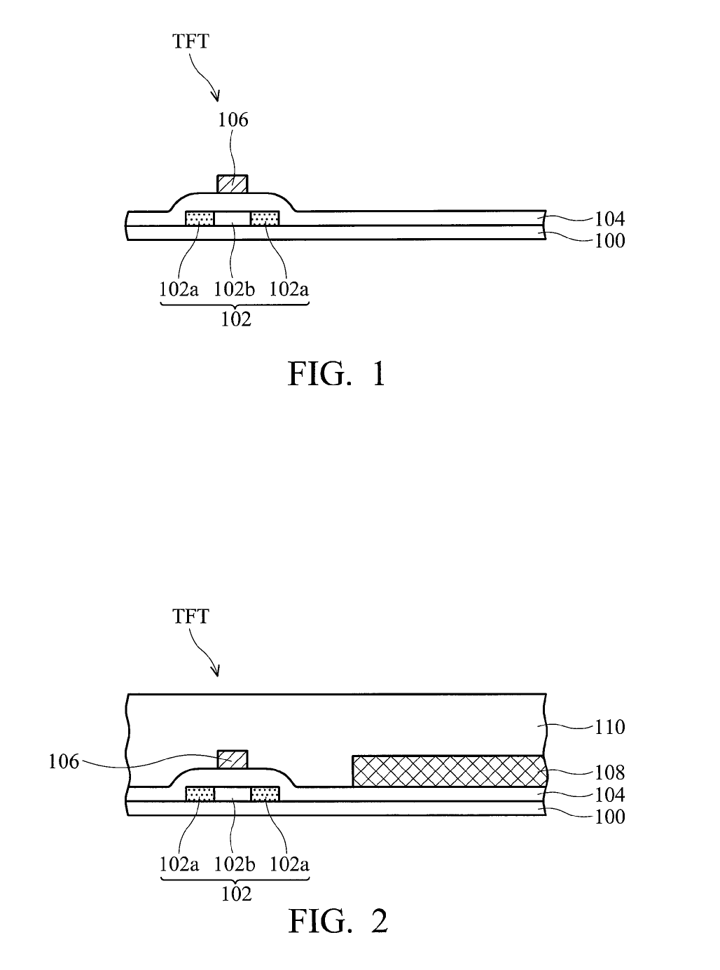

FIGS. 1-4 are a series of cross sections showing an exemplary embodiment of a method for fabricating an organic light emitting display device.

Referring now to FIG. 1, a substrate 100 is provided. The substrate 100 can be, for example, a transparent or non-transparent substrate and may comprise substrate glass or plastic materials. The substrate 100 comprises a thin film transistor TFT thereon. The thin film transistor TFT includes an active layer 102 formed over a portion of the substrate 100, a dielectric layer covering the active layer 102 and a gate electrode 106 formed over portions of the active layer 102. The dielectric layer 104 conformably covers the active layer 102 and may further extend over other portions of the substrate 100. The active layer 102 includes a pair of source/drain regions 102a and a tunnel region 102b formed therebetween. The thin film transistor TFT can be formed by conventional methods and materials, fabrication thereof will understood by those skilled in the art and are not described again here in detail, for simplicity.

Referring now to FIG. 2, a color filter layer 108 is formed, covering a portion of the dielectric layer 104. The color filter layer 108 covers the portion of the dielectric layer 104 not covering the thin film transistor TFT and may comprise photoresist materials with green, blue or red color. A photolithography process can thus form the color filter layer 108. The color filter layer 108 can also be made a predetermined color by doping layer with dyes of certain color such as red, green and blue. A planarization layer 110 is next blanketly formed to cover the substrate 100, and the thin film transistor TFT and the color filter layer 108 thereon. The planarization layer 100 can be formed by, for example the spin-on method, to thereby planarize the surface of the substrate 100 for facilitating the sequential processes.

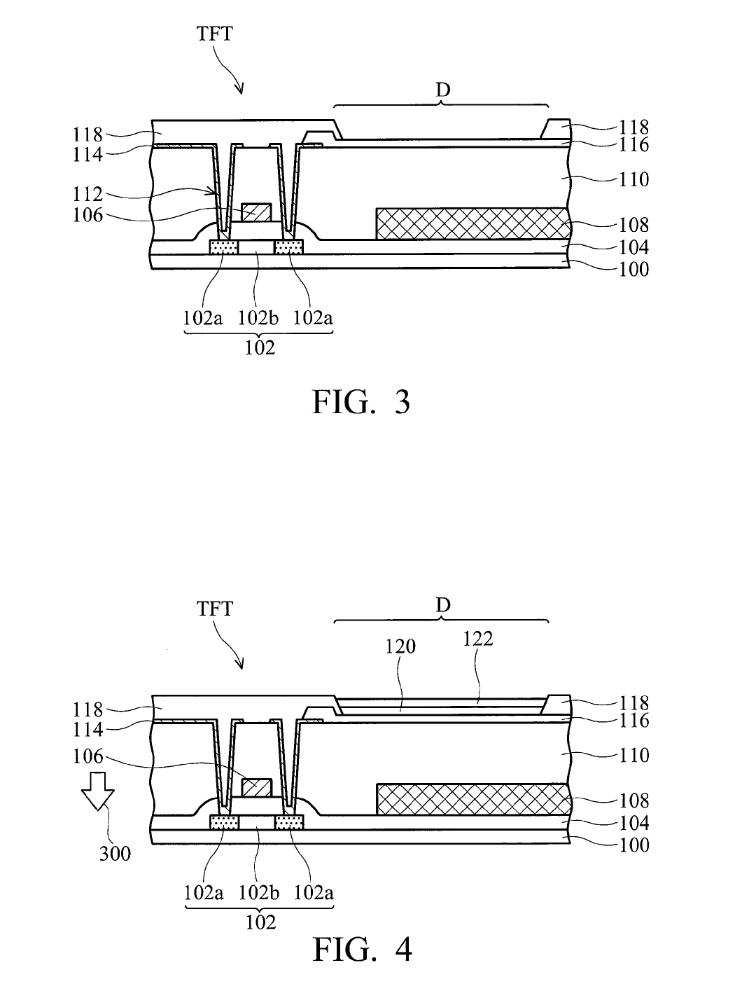

Referring now to FIG. 3, a photolithography and an etching process are next performed to thereby define a pair of openings 112 in the planarization layer 110. The openings 112 are substantially located over one of the source/drain regions 102a, respectively. Openings 112 are formed through the planarization layer 110 and the dielectric layer 104. A layer of conductive material is then conformably formed over the planarization layer 110 filling the openings 112. The layer of conductive material is then patterned by sequential photolithography and etching processes, forming conductive layer 114, as shown in FIG. 3. The conductive layer 114 can be formed by physical vapor deposition (PVD) or chemical vapor deposition (CVD), and preferably is formed by CVD to thereby a conductive layer with better step coverage performances in the openings. The conductive layer 114 may comprise Al, Mo, Cr, Cu, or the like metal materials.

Still referring to FIG. 3, another layer of conductive material is formed and patterned by sequential photolithography and etching processes, thereby forming the conductive layer 116. Herein, the conductive layer 114 may function as a contact for electrically connecting one of the source/drain regions 102 and the conductive layer 106. The conductive layer 116 covers a portion of the conductive layer 114 and may comprise transparent conductive materials such as ITO, IZO, or the like. The conductive layer 116 can be formed by, for example, PVD. Next, a cap layer 118 is blanketly formed over the substrate 100. The cap layer 118 is patterned by sequential photolithography and etching processes, thereby forming the patterned cap layer 118 with an opening therein, as illustrated in FIG. 3. The patterned cap layer 118 exposes portions of the conductive layer 116 to thereby define a display region D as a region for disposing organic light emitting display (OLED) units.

Referring now to FIG. 4, an organic light emitting layer 120 and a conductive layer 122 are sequentially formed over the conductive layer 116 within the display region D, thereby forming an OLED unit therein. Herein, the organic light emitting layer 120 is illustrated as a single layer but is not limited thereto. Those skilled in the art know the organic light emitting layer 120 further comprises sub-layers such as a hole-injection layer, a hole transport layer, a light emitting layer, an electron injection layer and an electron transport layer, and is referred to an organic light emitting layer here, for simplicity. The organic light emitting layer 120 may comprise materials such as Alq, TTBND/BTX-1, TPAC or TPD, thereby emitting white lights. The conductive layer 122 comprises Al, Cu, Ag or other metal materials.

Thus, as shown in FIG. 4, the conductive layer 116 of the organic light emitting unit disposed in the display region D may function as an anode and the conductive layer 122 may function as a cathode. Since the color filter layer 108 for emitting light of predetermined color such as red, green and blue is now disposed under the OLED unit. Therefore, the white light emitted by the organic light emitting layer 120 can be reflected by the conductive layer 122 and pass through the color filter layer 108 and the substrate 100. Arrow 300 illustrates a light emission direction of the OLED unit of FIG. 4.

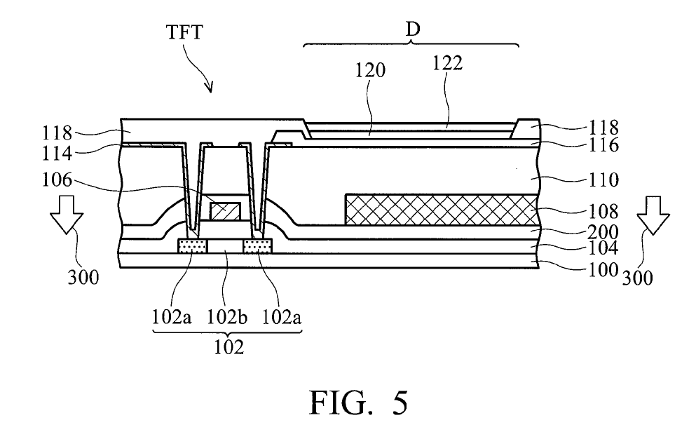

FIG. 5 is a cross section showing another exemplary OLED device similar to the OLED device illustrated in FIG. 4. As shown in FIG. 5, an interlayer dielectric layer 200 is now provided between the planarization layer 110, the color filter layer 108 and the dielectric layer 104, and the conductive layer 114 is formed through the interlayer dielectric layer 200 and the source/drain region 102a to form electrical connections.

Compared with the conventional technology, the disclosed OLED device has the following advantages. The OLED device integrates a color filter layer with an OLED unit therein, thereby preventing need for an additional color filter film as disclosed in the JP 2000-077191 patent application publication. Thus, fabrication costs and steps can be reduced.

The disclosed OLED device also employs a white light OLED layer, thereby preventing differences in life span of OLED units of different colors, thus, light-emitting performance is improved.

Moreover, the source/drain contact (e.g. the conductive layer 114 in FIGS. 3-5) is formed by CVD. Therefore, the structural performance and electrical reliability can be ensured and performance of the OLED device improved.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An organic light emitting display device, comprising:
a substrate;
a thin film transistor (TFT) formed over a first portion of the substrate;
a color filter layer formed over a second portion different from the first portion of the substrate;
a planarization layer overlying the color filter layer and the TFT;
a pair of openings formed through the planarization layer and portions of the TFT, respectively exposing a source/drain region of the TFT;
a pair of conductive layers conformably covering the openings and portions of the planarization layer adjacent thereto, electrically connecting one of the source/drain regions of the TFT, wherein one of the conductive layers extends toward the color filter layer and the conductive layers are electrically isolated from each other; and
an anode over the planarization layer, partially covering the conductive layer extending toward the color filter layer.

2. The device as claimed in claim 1, further comprising a cap layer partially covering the anode, thereby defining a display region.

3. The device as claimed in claim 1, wherein a gate dielectric layer of the TFT extends between the color filter layer and the substrate.

4. The device as claimed in claim 1, further comprising an interlayer dielectric layer formed between the color filter layer and the substrate, covering the TFT.

5. The device as claimed in claim 2, further comprising:
a white light-emitting layer formed over the anode within the display region; and
a cathode over the white light-emitting layer.

6. The device as claimed in claim 5, wherein the white light emitting layer emits light toward a direction to the substrate.

7. The device as claimed in claim 1, wherein the conductive layers comprise metal.

8. The device as claimed in claim 1, wherein the cathode comprises transparent conductive materials.

9. The device as claimed in claim 1, wherein the color filter layer comprises photoresist materials of red, blue or green color.

10. A method for fabricating an organic light emitting display device, comprising:
providing a substrate;
forming a thin film transistor over a first portion of the substrate, wherein a gate dielectric of the TFT at least covers the substrate in the first portion;
forming a color filter layer over a second portion different from the first portion of the substrate;
forming a planarization layer, covering the color filter layer and the TFT;
forming a pair of openings through the planarization layer and portions of the TFT, respectively exposing a source/drain region of the TFT;
conformably forming a pair of conductive layers, respectively covering the openings and portions of the planarization layer adjacent thereto, wherein one of the conductive layers extends toward the color filter layer and the conductive layers are electrically isolated from each other; and
forming an anode over the planarization layer, wherein the anode partially covers the conductive layer extending toward the color filter layer.

11. The method as claimed in claim 10, further comprising formation of an interlayer dielectric layer over the substrate prior to forming the planarization layer, the interlayer dielectric layer covers the TFT and the color filter layer and the openings formed through the interlayer dielectric layer.

12. The method as claimed in claim 10, wherein the conductive layers are formed by CVD.

13. The method as claimed in claim 12, wherein the conductive layers comprise metal.

14. The method as claimed in claim 10, wherein the anode is formed by PVD.

15. The method as claimed in claim 14, wherein the anode comprise transparent conductive material.

16. The method as claimed in claim 10, further comprising:
forming a cap layer, partially covering the anode and defining a display region;
forming a white light emitting layer over the anode within the display region; and
forming a cathode over the white light-emitting layer.

17. The method as claimed in claim 16, wherein the white light-emitting layer emits light toward a direction of the substrate.

18. The method as claimed in claim 10, wherein the color filter layer comprises photoresist materials of red, green or blue color.
